(19) United States
(12) Patent Application Publication
(10) Pub. No.: US 2022/0154325 A1
(43) Pub. Date: May 19, 2022

(54) ARTICLES COATED WITH CRACK-RESISTANT FLUORO-ANNEALED FILMS AND METHODS OF MAKING

(71) Applicant: ENTEGRIS, INC., Billerica, MA (US)

(72) Inventors: Nilesh Gunda, North Chelmsford, MA (US); Jijun Lao, North Billerica, MA (US); Samuel J. Angeloni, Plainville, MA (US); Wolfram Neff, Woburn, MA (US)

(21) Appl. No.: 17/527,228

(22) Filed: Nov. 16, 2021

Related U.S. Application Data
(60) Provisional application No. 63/115,375, filed on Nov. 18, 2020.

(51) Int. Cl. C23C 14/34; H01L 21/285; H01L 21/324; H01L 21/02; H01L 23/00

(52) U.S. Cl. CPC C23C 14/3471; H01L 21/2855; H01L 23/562; H01L 21/02192; H01L 21/324

(57) ABSTRACT

Articles and methods relating to coatings having superior plasma etch-resistance and which can prolong the life of RIE components are provided. An article has a vacuum compatible substrate and a protective film overlying at least a portion of the substrate. The film comprises a fluorinated metal oxide containing yttrium wherein the yttrium oxide is deposited using an AC power source. The film has a fluorine atomic % of at least 10 at a depth of 30% of the total thickness of the film and the film has no subsurface cracks below the surface of the film visible when using a laser confocal microscope to view the full depth of the film at a magnification of 1000×.

This application claims the benefit under 35 USC 119 of U.S. Provisional Patent Application No. 63/115,375, filed Nov. 18, 2020, the disclosure of which is hereby incorporated herein by reference in its entirety.

### BACKGROUND

Reactive-ion etching (RIE) is an etching technology used in semiconductor manufacturing processes. RIE uses chemically reactive plasma, which is generated by ionizing reactive gases (for example, gases that contain fluorine, chlorine, bromine, oxygen, or combinations thereof), to remove material deposited on wafers. However, the plasma not only attacks material deposited on wafers but also components installed inside the RIE chamber. Moreover, components used to deliver the reactive gases into the RIE chamber can also be corroded by reaction gases. The damage caused to components by plasma and/or reaction gases can result in low production yields, process instability, and contamination.

Semiconductor manufacturing etch chambers use components that are coated with chemically resistant materials to reduce degradation of the underlying component, to improve etch process consistency, and to reduce particle generation in the etch chambers. Despite being chemically resistant, the coatings can undergo degradation during cleaning and periodic maintenance where etchant gases combined with water or other solutions create corrosive conditions, for example hydrochloric acid, that degrade the coatings. The corrosive conditions can shorten the useful life of the coated component and may also lead to etch chamber contamination when the components are reinstalled in the chamber. There is a continuing need for improved coatings for etch chamber components.

### SUMMARY

Articles and methods relating to coatings having superior plasma etch-resistance and which can prolong the life of RIE components are provided. The coatings also have minimal to no visible surface cracks on the surface of the coating or visible subsurface cracks within the coating.

In a first aspect of the disclosure, an article comprises a substrate; and a protective film overlying at least a portion of the substrate, wherein the film comprises a fluorinated metal oxide containing yttrium, wherein the film has a fluorine atomic % of at least 10 at a depth of 30% of the total thickness of the film, and

wherein the film has no subsurface cracks below the surface of the film visible
when using a laser confocal microscope to view the full depth of the film at a magnification of 1000×.

In a second aspect according to the first aspect, after fluoro-annealing, the film has no surface cracks on the surface of the film visible when viewing the surface of the film with a laser confocal microscope at a magnification of 400×.

In a third aspect according to the first or second aspect, the substrate is alumina.

In a fourth aspect according to the first or second aspect, the substrate is silicon.

In a fifth aspect according to any preceding aspect, the film has a fluorine atomic % of at least 20 at a depth of 30% of the total thickness of the film.

In a sixth aspect according to any preceding aspect, the film has a fluorine atomic % of at least 30 at a depth of 30% of the total thickness of the film.

In a seventh aspect according to any preceding aspect, the film has a fluorine atomic % of at least 10 at a depth of 50% of the total thickness of the film.

In an eighth aspect according to any preceding aspect, the film has a fluorine atomic % of at least 20 at a depth of 50% of the total thickness of the film.

In a ninth aspect according to any preceding aspect, the film has a fluorine atomic % of at least 30 at a depth of 50% of the total thickness of the film.

In a tenth aspect of the disclosure, a method comprises depositing a metal oxide containing yttrium onto a substrate using a physical vapor deposition technique using an alternating current (AC) power supply, the metal oxide forming a film overlying the substrate; and fluoro-annealing the film, wherein after fluoro-annealing, the film has a fluorine atomic % of at least 10 at a depth of 30% of the total thickness of the film.

In an eleventh aspect according to the tenth aspect, after fluoro-annealing, the film has no surface cracks on the surface the film visible when viewing the surface of the film with a laser confocal microscope at a magnification of 400×.

In a twelfth aspect according to the tenth or eleventh aspect, after fluoro-annealing, the film has no subsurface cracks below the surface of the film visible when using a laser confocal microscope to view the full depth of the film at a magnification of 1000×.

In a thirteenth aspect according to any of the tenth through twelfth aspects, after fluoro-annealing, the film has a fluorine atomic % of at least 20 at a depth of 30% of the total thickness of the film.

In a fourteenth aspect according to any of the tenth through twelfth aspects, after fluoro-annealing, the film has a fluorine atomic % of at least 30 at a depth of 30% of the total thickness of the film.

In a fifteenth aspect according to any of the tenth through fourteenth aspects, after fluoro-annealing, the film has a fluorine atomic % of at least 20 at a depth of 50% of the total thickness of the film.

In a sixteenth aspect according to any of the tenth through fourteenth aspects, after fluoro-annealing, the film has a fluorine atomic % of at least 30 at a depth of 50% of the total thickness of the film.

In a seventeenth aspect according to any of the tenth through sixteenth aspects, the fluoro-annealing is performed at a temperature of about 300° C. to about 650° C. in fluorine containing atmosphere.

In an eighteenth aspect according to any of the tenth through seventeenth aspects, the substrate is alumina.

In a nineteenth aspect according to any of the tenth through seventeenth aspects, the substrate is silicon.

In a twentieth aspect, the article is made according to the process of any of the tenth through nineteenth aspects.

### BRIEF DESCRIPTION OF THE DRAWINGS

The foregoing will be apparent from the following more particular description of example embodiments of the disclosure, as illustrated in the accompanying drawings in which like reference characters refer to the same parts throughout the different views. The drawings are not necessarily to scale, emphasis instead being placed upon illustrating embodiments of the present disclosure.

FIG. 1 is a plot of the data is shown in FIG. 1 with Fluorine atomic % shown on the Y axis and depth into the thickness in microns on the X axis;

FIG. 2 is a cross-section view of a silicon coupon from Example 1 after fluoro-annealing taken by a scanning electron microscope (SEM);

FIG. 3 is a photograph taken with a Keyence laser confocal microscope at a magnification of 1000× and shows multiple surface cracks in the fluorinated yttrium oxide film subjected to condition 10 in Example 1; and

FIG. 4 is a photograph taken with a Keyence laser confocal microscope at a magnification of 1000× and shows that there are no surface cracks in the fluorinated yttrium oxide film subjected to condition 10 in Example 2.

### DETAILED DESCRIPTION

While this disclosure will be particularly shown and described with references to example embodiments thereof, it will be understood by those skilled in the art that various changes in form and details may be made therein without departing from the scope of the disclosure encompassed by the appended claims.

While various compositions and methods are described, it is to be understood that this disclosure is not limited to the particular molecules, compositions, designs, methodologies or protocols described, as these may vary. It is also to be understood that the terminology used in the description is for the purpose of describing the particular versions or versions only, and is not intended to limit the scope of the present disclosure which will be limited only by the appended claims.

It must also be noted that as used herein and in the appended claims, the singular forms “a”, “an”, and “the” include plural reference unless the context clearly dictates otherwise. Thus, for example, reference to a “film” is a reference to one or more films and equivalents thereof known to those skilled in the art, and so forth. Unless defined otherwise, all technical and scientific terms used herein have the same meanings as commonly understood by one of ordinary skill in the art. Methods and materials similar or equivalent to those described herein can be used in the practice or testing of versions of the present disclosure. All publications mentioned herein are incorporated by reference in their entirety. Nothing herein is to be construed as an admission that the disclosure is not entitled to antedate such disclosure by virtue of prior disclosure. “Optional” or “optionally” means that the subsequently described event or circumstance may or may not occur, and that the description includes instances where the event occurs and instances where it does not. All numeric values herein can be modified by the term “about,” whether or not explicitly indicated. The term “about” generally refers to a range of numbers that one of skill in the art would consider equivalent to the recited value (i.e., having the same function or result). In some versions the term “about” refers to ±10% of the stated value, in other versions the term “about” refers to ±2% of the stated value. While compositions and methods are described in terms of “comprising” various components or steps (interpreted as meaning “including, but not limited to”), the compositions and methods can also “consist essentially of” or “consist of” the various components and steps, such terminology should be interpreted as defining essentially closed-member groups.

A description of example embodiments of the disclosure follows.

Coatings, including yttria (yttrium oxide), are used on RIE components to provide plasma etching resistance. Such coatings can be applied to RIE components by various methods, including thermal spray, aerosol, physical vapor deposition (PVD), chemical vapor deposition (CVD), and E-beam evaporation. However, yttria coatings can be corroded by hydrogen chloride (HCl) during maintenance of the RIE chamber and components.

Following a chlorine plasma RIE process, residual chlorine remains on the RIE components. When the components are cleaned by deionized (DI) water during maintenance, the residual chlorine and DI water become HCl, which can corrode the yttria coating, preventing the yttria coating from protecting the underlying substrate during the next RIE process. Additionally, yttria coatings in an RIE chamber can particulate during the plasma etching process. The particles can fall on the silicon wafer, causing defects to the manufactured semiconductor device and causing losses to wafer production yields.

Versions of the present disclosure provide improved articles and methods for protecting RIE components by fluoro-annealing metal oxide yttrium-containing films, such as yttria and yttrium aluminum oxide that have minimal to no surface cracks on the surface of the film and minimal to no subsurface cracks in the film. Previous films having surface cracks and subsurface cracks were formed when the yttria deposition process relied on a pulsed direct current (DC) power source. As disclosed herein, use of an alternating current (AC) power source during the yttria deposition process can unexpectedly minimize or prevent the formation of surface cracks and subsurface cracks during a fluoro-annealing process. As used herein, “a surface crack” is a crack on the surface of the film that is visible when viewing the surface of the film with a laser confocal microscope at a magnification of 400×. As used herein, “a subsurface crack” is a crack below the surface of the film that is visible when using a laser confocal microscope to view the full depth of the film at a magnification of 1000×.

The fluoro-annealing process includes introducing fluorine into metal oxide yttrium-containing films by annealing the films at 300° C.˜650° C. in a fluorine containing atmosphere. The heating ramp rate of the fluoro-annealing process can be between from 50° C. per hour to 200° C. per hour.

Fluoro-annealed yttria films offer several advantages and have several desirable characteristics, including a high fluorine plasma etch resistance (e.g., about 0.1 to about 0.2 microns/hr), a high wet chemical etch resistance (e.g., about 5 to about 120 minutes in 5% HCl), good adhesion to chamber components (e.g., second critical load (LC2) adhesion of about 5N to about 15N), and conformal coating ability. Additionally, the fluoro-annealed yttria films are tunable in terms of material, mechanical properties, and microstructure Films comprising yttria, fluoro-annealed yttria, or a mixture of both yttria and fluoro-annealed yttria can be created to meet the needs of a specific application or etching environment. For example, a fluorine content of a film can be manipulated to be from about 4 atomic percent to about 60 atomic percent as measured by a scanning electron microscope (SEM) in combination with an energy dispersive spectroscopy (EDS) probe, and a fluorine depth can be manipulated to be about 0.5 microns to about 20 microns. The etch resistance of fluorinated yttria increases with fluorine content in the film. Fluoro-annealed yttria films disclosed herein deposited using an AC power source also offer the additional advantages of superior crack resistance (both in terms of surface cracks and subsurface cracks) and improved integrity at elevated temperatures versus fluoro-annealed yttria films deposited using a DC or pulsed DC power source.

In some embodiments yttria is deposited on a substrate using an alternating current (AC) power source followed by a fluoro-annealing process to convert yttria to yttrium oxyfluoride or to a mixture of yttria and yttrium oxyfluoride. The yttria and/or yttrium oxyfluoride form a film overlying and protecting the substrate. The film provides an outermost layer that is in contact with the etching environment in the vacuum chamber.

A film of a metal oxide containing yttrium, such as yttria and yttrium aluminum oxide, is first deposited onto a substrate. The deposition of the metal oxide film can occur by various methods of physical vapor deposition (PVD) using an AC power source, including sputtering and ion beam assisted deposition. The AC power source can be operated at a frequency in a range from about 30 kHz to about 100 kHz. Following deposition, the film is fluoro-annealed at about 300° C. to about 650° C. in an environment containing fluorine. The fluorination process can be performed as described in U.S. Pub. No. 2016/0273095, which is hereby incorporated by reference in its entirety. The fluorination process can be performed using several methods, including, for example, fluorine ion implantation followed by annealing, fluorine plasma processing at 300° C. or above, fluoropolymer combustion methods, fluorine gas reactions at elevated temperatures, and UV treatments with fluorine gas, or any combination of the foregoing.

Various sources of fluorine can be used depending upon the fluoro-annealing method employed. For fluoropolymer combustion methods, fluorine polymer material is needed and can be, for example, PVF (polyvinylfluoride), PVDF (polyvinylidene fluoride), PTFE (polytetrafluoroethylene), PCTFE (polychlorotrifluoroethylene), PFA, MFA (perfluoroalkoxy polymer), FEP (fluorinated ethylene-propylene), ETFE (polyethylenetetrafluoroethylene), ECTFE (polyethylenechlorotrifluoroethylene), FFPM/FFKM (Perfluorinated Elastomer [Perfluoroelastomer]), FPM/FKM (Fluorocarbon lChlorotrifluoroethylenevinylidene fluoride]), PFPE (Perfluoropolyether), PFSA (Perfluorosulfonic acid), and Perfluoropolyoxetane.

For other fluoro-annealing methods, including fluorine ion implantation followed by annealing, fluorine plasma processing at 300° C. or above, fluorine gas reactions at elevated temperatures, and UV treatments with fluorine gas, fluorinated gases and oxygen gases are needed for reaction. Fluorinated gases can be, for example, hydrofluorocarbons (HFCs), perfluorocarbons (PFCs), sulfur hexafluoride (SF₆), HF vapor, NF3, and gas from fluoropolymer combustion.

The yttria or yttrium aluminum oxide film is preferably columnar in structure, such that the structure permits fluorine to penetrate the film through grain boundaries during the fluoro-annealing process. An amorphous yttria structure (i.e., non-columnar, or less-columnar) does not permit fluorine to penetrate as easily during the fluoro-annealing process.

Fluoro-annealed films of the present disclosure can be applied to vacuum compatible substrates, such as components in a semiconductor manufacturing system. Etch chamber components can include shower heads, shields, nozzles, and windows. The etch chamber components can also include stages for substrates, wafer handling fixtures, and chamber liners. The chamber components can be made from ceramic materials. Examples of ceramic materials include alumina, silicon carbide, and aluminum nitride. Although the specification refers to etch chamber components, embodiments disclosed herein are not limited to etch chamber components and other ceramic articles and substrates that would benefit from improved corrosion resistance can also be coated as described herein. Examples include ceramic wafer carriers and wafer holders, susceptors, spindles, chuck, rings, baffles, and fasteners. Vacuum compatible substrates can also be silicon, quartz, steel, metal, or metal alloy. Vacuum compatible substrates can also be or include plastics used for example in the semiconductor industry, such as polyether ether ketone (PEEK) and polyimides, for example in dry etching.

The fluoro-annealing films are tunable, with the fluoro-annealing process allowing for variations in depth and density of the fluorination of the films. In some embodiments, the fluoro-annealed film is completely fluorinated (fully saturated), with fluorine located throughout the depth of the film. In other embodiments, the fluoro-annealed film is partially fluorinated, with fluorine located along an outer portion of the film but not throughout the entire depth of the film. In addition, the film can be a graded film, with the fluorine content varying over the depth of the film. For example, the top (outermost) portion of the film may include the highest fluorine content, with the fluorine content gradually decreasing over the depth the film toward the bottom (innermost) portion of the film that is closest to and interfaces with the substrate. The outermost portion of the film is that which faces the etching environment. In some embodiments, a film can include a surface fluorine amount of about 60 atomic % or less, about 55 atomic % or less, about 50 atomic % or less, about 45 atomic % or less, about 40 atomic % or less, about 35 atomic % or less, about 30 atomic % or less, about 25 atomic % or less, about 20 atomic % or less, about 15 atomic % or less. All atomic % of fluorine values disclosed herein are measured using a scanning electron microscope (SEM) in combination with an energy dispersive spectroscopy (EDS) probe. In some embodiments, the film may have a thickness in a range from about 1 micron to about 20 microns. In some embodiments, the amount of fluorine at a depth of 10% of the film thickness (as measured from the surface furthest from the substrate) is at least about 10 atomic %, about 15 atomic %, about 20 atomic %, about 25 atomic %, about 30 atomic %, or about 35 atomic %. In some embodiments, the amount of fluorine at a depth of 30% of the film thickness (as measured from the surface furthest from the substrate) is at least about 10 atomic %, about 15 atomic %, about 20 atomic %, about 25 atomic %, about 30 atomic %, or about 35 atomic %. In some embodiments, the amount of fluorine at a depth of 50% of the film thickness (as measured from the surface furthest from the substrate) is at least about 10 atomic %, about 15 atomic %, about 20 atomic %, about 25 atomic %, about 30 atomic %, or about 35 atomic %.

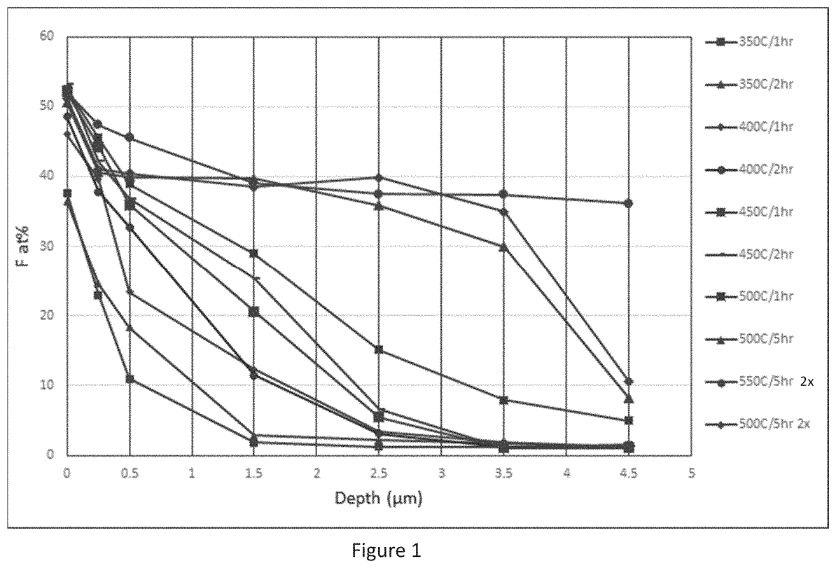

The depth of the fluorination of the film can be controlled during fluoro-annealing by varying process parameters such as fluoro-annealing time and temperature. As shown in FIG. 1 (and described in more detail in Example 1 below), fluorine diffuses deeper into the film with higher fluoro-annealing time and temperature.

The film provides a protective layer overlying the substrate, the protective layer being an outermost layer of a coated article that is in contact with the environment inside the vacuum chamber.

In some embodiments where the film is not fully fluorinated, the top or outermost portion of the film is yttrium oxyfluoride and a remaining depth of the film is yttria. In other embodiments where the film is not fully fluorinated, the top or outermost portion of the film is yttrium aluminum oxyfluoride and a remaining dept of the film is yttrium aluminum oxide.

In some embodiments, the substrate has been coated with yttrium through physical vapor deposition in an oxygen containing atmosphere using an AC power source. In some embodiments, the substrate has been coated with yttrium through reactive sputtering in a reactive gas atmosphere. The reactive gas can be one that is a source of oxygen and can include air. Thus, the film can be a ceramic material that includes yttrium and oxygen and can made using physical vapor deposition (PVD) techniques such as reactive sputtering. The oxygen containing atmosphere during deposition can also include inert gases such as argon.

In some embodiments, disclosed herein is a ceramic substrate that has been coated with yttria film deposited by reactive sputtering using an AC power supply where the coating and the substrate are annealed in an oven containing a fluorine atmosphere at 300° C.˜650° C. The fluoro-annealed coating is a ceramic material that includes yttrium, oxygen, and fluorine. The substrate and fluoro-annealed film can be baked at 150 degrees centigrade under high vacuum (5E-6 torr) without loss of fluorine from the coating.

The duration of time for annealing the yttria films at an elevated temperature can be from about 0.5 hours to about 6.5 hours or more.

The fluoro-annealing of yttria on a ceramic substrate, such as alumina, significantly improves the wet chemical (5% HCl) etch resistance of the yttria film.

The fluoro-annealed yttria film disclosed herein can be characterized as those that adhere to an underlying ceramic substrate, the film adhering to the ceramic substrate after 5 or more minutes contact with 5% aqueous hydrochloric acid at room temperature. In some versions the fluoro-annealed yttria films adhere to the underlying ceramic substrate for between 15 minutes and 30 minutes, in some cases 30 minutes to 45 minutes, and in still other cases the films at adhere to the underlying substrate after 100-120 minutes when contacted or submerged in 5% aqueous HCl at room temperature. Yttria films disclosed herein can be used as protective coatings for components used in halogen gas containing plasma etchers. For example, halogen containing gases can include NF₃, F₂, Cl₂ and the like.

Fluoro-annealed yttria films are particularly advantageous in fluorine based etching systems because the presence of fluorine in the film allows the chamber to stabilize or season more quickly. This helps to eliminate process drift during seasoning and use, and reduces etcher downtime for seasoning with a fluorine or chlorine containing gas.

As discussed above, the fluoro-annealed yttria films disclosed herein have minimal to no surface cracks and/or subsurface cracks. The superior crack resistance of the film is believed to be attributed to depositing the yttria films utilizing an AC power source. The yttria films deposited using an AC power source rather than a DC or pulsed DC power source have minimal (e.g., 5 crack or less, 4 cracks or less, 3 cracks or less, or 2 cracks or less) to no surface cracks and/or subsurface cracks, including for substrates having a significant difference in coefficients of thermal expansion with yttria such as quartz substrates. The formation of minimal (e.g., 5 crack or less, 4 cracks or less, 3 cracks or less, or 2 cracks or less) to no surface cracks and/or subsurface cracks is also present after fluorinating the yttria films including when the fluoro-annealing is conduct at high temperatures and/or durations, thereby leading to higher fluorine atomic % throughout the depth of the film. For example, minimal to no surface cracks are visible on the surface of the film when viewing the surface of the film with an laser confocal microscope at a magnification of 400× and/or minimal to no subsurface cracks are visible below the surface of the film when using a laser confocal microscope to view the full depth of the film at a magnification of 1000× for films having a fluorine atomic % of at least 10 at a depth of 30% of the total thickness of the film, a fluorine atomic % of at least 20 at a depth of 30% of the total thickness of the film, a fluorine atomic % of at least 30 at a depth of 30% of the total thickness of the film, a fluorine atomic % of at least 10 at a depth of 50% of the total thickness of the film, a fluorine atomic % of at least 20 at a depth of 50% of the total thickness of the film, a fluorine atomic % of at least 30 at a depth of 50% of the total thickness of the film. These results are unexpected because films with similar fluorine atomic % depth profiles where the yttria film is deposited using a DC or pulsed DC power source result in surface cracks and/or subsurface cracks.

### Example 1

A yttrium oxide film having a thickness of about 5 microns were deposited by yttrium physical vapor deposition in an oxygen containing atmosphere (i.e., reactive sputtering) onto coupon-sized substrates (approximately 0.75 in by 0.75 in) of silicon using an alternating current (AC) power source. Next the coupons were subjected to fluoro-annealing during which the coupons were heated in an oven in a fluorine-containing atmosphere under one of the following conditions listed in the Table 1 below. Conditions 9 and 10 had double the amount of fluorine precursor as conditions 1 through 8 in order to ensure all the fluorine did not get used up before the end of the fluoro-annealing treatment. The atomic % of fluorine was measured throughout the 5 micron thickness of the film for coupons subjected to each of the 10 conditions listed in the Table 1 using a scanning electron microscope in combination with an electron dispersive spectroscopy (EDS) probe. A plot of the data is shown in FIG. 1 with Fluorine atomic % shown on the Y axis and depth into the thickness in microns on the X axis. The “2×” in the legend of FIG. 1 for 500C/5 hr 2× and 550C/5 hr 2× refers to there being double the amount of fluorine precursor for those conditions. The surface of the coating of each coupon was viewed under a laser confocal microscope at a magnification of 400× to inspect for visible surface cracks on the surface of the coating. The coating of each coupon was also viewed with a laser confocal microscope to view the full depth of the film at a magnification of 1000× to inspect for subsurface cracks below the surface of the coating. Table 1 also reports if surface cracks and subsurface cracks were visible for each of the ten conditions.

TABLE 1
Fluorinated Yttrium Oxide Films on Silicon Substrates

| | Temperature | Time | Surface | Subsurface |
|---|---|---|---|---|
| Condition | (C.) | (hours) | Cracks | Cracks |
| 1 | 350 | 1 | No | No |
| 2 | 350 | 2 | No | No |
| 3 | 400 | 1 | No | No |
| 4 | 400 | 2 | No | No |
| 5 | 450 | 1 | No | No |
| 6 | 450 | 2 | No | No |
| 7 | 500 | 1 | No | No |
| 8 | 500 | 5 | No | No |
| 9* | 500 | 5 | No | No |
| 10* | 550 | 5 | Yes | Yes |

*Conditions 9 and 10 had double the amount of fluorine precursor than conditions 1-8.

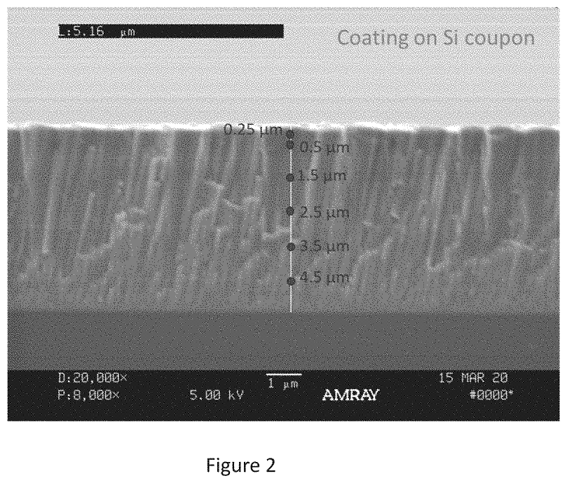

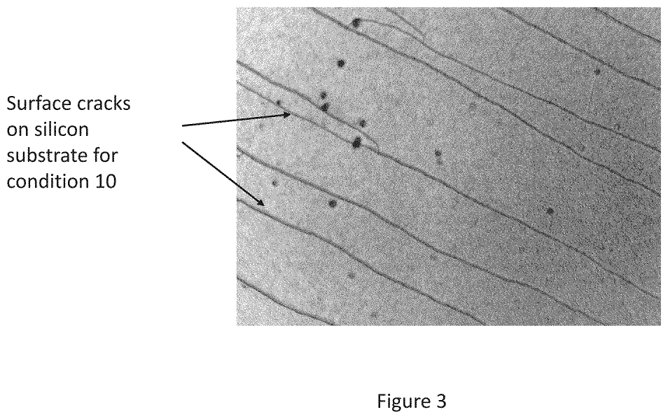

As can be seen in FIG. 1, there is a general trend going from condition 1 to condition 10 that fluorine atomic % at the surface of the coating increases with increasing fluoro-annealing temperature and duration. It can also be seen in FIG. 1, that the fluorination through the thickness of the coating is achieved for conditions 6 7, 8, and 9. FIG. 2 is a cross-section view of a coupon subjected to one of the above fluoro-annealing conditions taken by a scanning electron microscope (SEM). As shown in Table 1, surface cracks and subsurface cracks did not occur until condition 10 at 550 degrees Celsius. FIG. 3 is a photograph taken with a Keyence laser confocal microscope at a magnification of 1000× and shows multiple surface cracks It is believed that the lack of visible surface and subsurface cracks in the coating for conditions 1 through 9 is due to the use of an alternating current (AC) power source during the yttrium oxide deposition.

### Example 2

A yttrium oxide film having a thickness of about 5 microns were deposited by yttrium physical vapor deposition in an oxygen containing atmosphere (i.e., reactive sputtering) onto coupon-sized substrates (approximately 0.75 inch diameter disc) of alumina using an alternating current (AC) power source. Next the coupons were subjected to fluoro-annealing during which the coupons were heated in an oven in a fluorine-containing atmosphere under one of the following conditions listed in the Table 2 below. Conditions 9 and 10 had double the amount of fluorine precursor as conditions 1 through 8 in order to ensure all the fluorine did not get used up before the end of the fluoro-annealing treatment. It is believed that a plot of Fluorine atomic % shown on the Y axis and depth into the thickness in microns on the X axis for each the coupons subjected to conditions 1 through 10 would be similar to that shown in FIG. 1. The surface of the coating of each coupon was viewed under laser confocal microscope at a magnification of 400× to inspect for visible surface cracks on the surface of the coating. The coating of each coupon was also viewed with a laser confocal microscope to view the full depth of the film at a magnification of 1000× to inspect for subsurface cracks below the surface of the coating. Table 2 also reports if surface cracks and subsurface cracks were visible for each of the ten conditions.

TABLE 2
Fluorinated Yttrium Oxide Films on Alumina Substrates

| | Temperature | Time | Surface | Subsurface |
|---|---|---|---|---|
| Condition | (C.) | (hours) | Cracks | Cracks |
| 1 | 350 | 1 | No | No |
| 2 | 350 | 2 | No | No |
| 3 | 400 | 1 | No | No |
| 4 | 400 | 2 | No | No |
| 5 | 450 | 1 | No | No |
| 6 | 450 | 2 | No | No |
| 7 | 500 | 1 | No | No |
| 8 | 500 | 5 | No | No |
| 9 | 500 | 5 | No | No |
| 10 | 550 | 5 | No | No |

*Conditions 9 and 10 had double the amount of fluorine precursor than conditions 1-8.

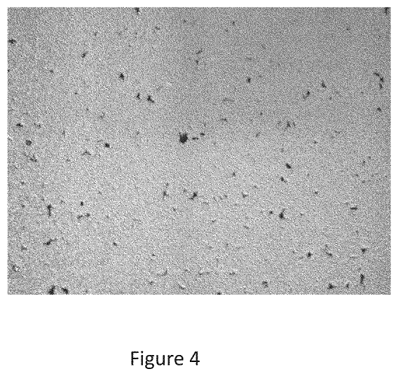

It is believed that the lack of visible surface and subsurface cracks in the coating for conditions 1 through 10 is due to the use of an alternating current (AC) power source during the yttrium oxide deposition. FIG. 4 is a photograph taken with a Keyence laser confocal microscope at a magnification of 1000× and shows that there are no surface cracks.

### Example 3

A yttrium oxide film having a thickness of about 5 microns were deposited by yttrium physical vapor deposition in an oxygen containing atmosphere (i.e., reactive sputtering) onto coupon-sized substrates (approximately 0.75 inches in diameter) of quartz and sapphire using an alternating current (AC) power source. Next the coupons were subjected to fluoro-annealing during which the coupons were heated in an oven in a fluorine-containing atmosphere under conditions 1 through 10 used in Examples 1 and 2. There were no surface cracks or subsurface cracks in the yttrium oxide film as coated, however cracks and subsurface cracks did form after performing the fluoro-annealing under each of conditions 1 through 10.

The teachings of all patents, published applications and references cited herein are incorporated by reference in their entirety.

Although the disclosure has been shown and described with respect to one or more implementations, equivalent alterations and modifications will occur to others skilled in the art based upon a reading and understanding of this specification and the annexed drawings.

The disclosure includes all such modifications and alterations and is limited only by the scope of the following claims. In addition, while a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant to mean an example, rather than the best. It is also to be appreciated that features and/or elements depicted herein are illustrated with particular dimensions and/or orientations relative to one another for purposes of simplicity and ease of understanding, and that the actual dimensions and/or orientations may differ substantially from that illustrated herein.

While this disclosure has been particularly shown and described with references to example embodiments thereof, it will be understood by those skilled in the art that various changes in form and details may be made therein without departing from the scope of the disclosure encompassed by the appended claims.

What is claimed is:

1. An article comprising:
a substrate; and
a protective film overlying at least a portion of the substrate,
wherein the film comprises a fluorinated metal oxide containing yttrium,
wherein the film has a fluorine atomic % of at least 10 at a depth of 30% of the total thickness of the film, and
wherein the film has no subsurface cracks below the surface of the film visible when using a laser confocal microscope to view the full depth of the film at a magnification of 1000×.

2. The article of claim 1, wherein after fluoro-annealing, the film has no surface cracks on the surface of the film visible when viewing the surface of the film with a laser confocal microscope at a magnification of 400×.

3. The article of claim 1, wherein the substrate is alumina.

4. The article of claim 1, wherein the substrate is silicon.

5. The article of claim 1, wherein the film has a fluorine atomic % of at least 20 at a depth of 30% of the total thickness of the film.

6. The article of claim 1, wherein the film has a fluorine atomic % of at least 30 at a depth of 30% of the total thickness of the film.

7. The article of claim 1, wherein the film has a fluorine atomic % of at least 10 at a depth of 50% of the total thickness of the film.

8. The article of claim 1, wherein the film has a fluorine atomic % of at least 20 at a depth of 50% of the total thickness of the film.

9. The article of claim 1, wherein the film has a fluorine atomic % of at least 30 at a depth of 50% of the total thickness of the film.

10. A method comprising:
depositing a metal oxide containing yttrium onto a substrate using a physical vapor deposition technique using an alternating current (AC) power supply, the metal oxide forming a film overlying the substrate; and
fluoro-annealing the film,
wherein after fluoro-annealing, the film has a fluorine atomic % of at least 10 at a depth of 30% of the total thickness of the film.

11. The method of claim 10, wherein after fluoro-annealing, the film has no surface cracks on the surface the film visible when viewing the surface of the film with a laser confocal microscope at a magnification of 400×.

12. The method of claim 10, wherein after fluoro-annealing, the film has no subsurface cracks below the surface of the film visible when using a laser confocal microscope to view the full depth of the film at a magnification of 1000×.

13. The method of claim 10, wherein after fluoro-annealing, the film has a fluorine atomic % of at least 20 at a depth of 30% of the total thickness of the film.

14. The method of claim 10, wherein after fluoro-annealing, the film has a fluorine atomic % of at least 30 at a depth of 30% of the total thickness of the film.

15. The method of claim 10, wherein after fluoro-annealing, the film has a fluorine atomic % of at least 20 at a depth of 50% of the total thickness of the film.

16. The method of claim 10, wherein after fluoro-annealing, the film has a fluorine atomic % of at least 30 at a depth of 50% of the total thickness of the film.

17. The method of claim 10, wherein the fluoro-annealing is performed at a temperature of about 300° C. to about 650° C. in fluorine containing atmosphere.

18. The method of claim 10, wherein the substrate is alumina.

19. The method of claim 10, wherein the substrate is silicon.

20. An article made according to the process of claim 10.
